(19) United States
(12) Patent Application Publication
(10) Pub. No.: US 2026/0198018 A1
(43) Pub. Date: Jul. 9, 2026

(54) MEMORY DEVICE, SEMICONDUCTOR PACKAGE INCLUDING THE SAME, AND METHOD OF FABRICATING THEREOF

(71) Applicant: SK hynix Inc., Gyeonggi-do (KR)

(72) Inventor: Heon Yong CHANG, Gyeonggi-do (KR)

(21) Appl. No.: 19/209,748

(22) Filed: May 15, 2025

(30) Foreign Application Priority Data
Jan. 6, 2025 (KR) 10-2025-0001532

(51) Int. Cl. H10B 80/00; H01L 23/00; H01L 25/00; H01L 25/065; H01L 25/18; H10B 12/00

(52) U.S. Cl. CPC H10B 80/00; H10B 12/315; H10B 12/50; H10W 90/00; H10W 80/312; H10W 80/327; H10W 90/297; H10W 90/792

(57) ABSTRACT

A memory device and a semiconductor package with the same according to embodiments of the present disclosure may include a first semiconductor structure including a substrate and a through-electrode penetrating the substrate, a second semiconductor structure positioned over the first semiconductor structure, a bonding insulating layer disposed between the first semiconductor structure and the second semiconductor structure, and connection contact plugs penetrating the bonding insulating layer to electrically connect the first semiconductor structure and the second semiconductor structure, at least one of the connection contact plugs being electrically connected to the through-electrode.

### CROSS-REFERENCE TO RELATED APPLICATION

The present application claims priority under 35 U.S.C. 119(a) to Korean patent application number 10-2025-0001532 filed on Jan. 6, 2025, which is incorporated herein by reference in its entirety.

### TECHNICAL FIELD

Embodiments of the present disclosure relate to a memory device and a semiconductor package including the memory device, and a method of fabricating the memory device.

### BACKGROUND

Technology for stacking semiconductor chips is an area of interest in response to the demand for high integration of semiconductor packages. In order to electrically connect the stacked semiconductor chips, technology such as a through-silicon-via (TSV) technology or a technology for bonding chips using bonding pads or solders may be used.

In addition, in response to the increasing demand for high integration, technologies for 3D integration of memory devices, such as wafer bonding technology, are being used.

However, technologies for high integration of semiconductor packages and memory devices may have technological limitations.

### SUMMARY

Embodiments of the disclosure may provide a memory device capable of achieving high integration using wafer bonding technology, a semiconductor package including the same, and a method of fabricating thereof.

The objects of the embodiments of the present disclosure are not limited to the objects described in this specification, and other objects not mentioned will be clearly understood by those skilled in the art from the description below.

Embodiments of the disclosure may provide a memory device including a first semiconductor structure including a substrate and a through-electrode penetrating the substrate, a second semiconductor structure positioned over the first semiconductor structure, a bonding insulating layer disposed between the first semiconductor structure and the second semiconductor structure, and connection contact plugs penetrating the bonding insulating layer to electrically connect the first semiconductor structure and the second semiconductor structure, at least one of the connection contact plugs being electrically connected to the through-electrode.

Embodiments of the disclosure may provide a semiconductor package including a first semiconductor chip, and a second semiconductor chip stacked on the first semiconductor chip, wherein the first semiconductor chip includes a first semiconductor structure including a first substrate and a first through-electrode penetrating the first substrate, a second semiconductor structure positioned over the first semiconductor structure, first connection contact plugs disposed to electrically connect the first semiconductor structure and the second semiconductor structure, at least one of the first connection contact plugs being electrically connected to the first through-electrode, a first front pad positioned on one surface of the second semiconductor structure, and a first back pad positioned on one surface of the first semiconductor structure and connected to the first through-electrode.

Embodiments of the disclosure may provide A method of fabricating a memory device including forming a capping insulating layer on a first lower insulating layer of a first semiconductor structure, forming a first through-electrode penetrating the first semiconductor structure, forming a bonding insulating layer disposed between the first semiconductor structure and a second semiconductor structure, bonding the second semiconductor structure to the first semiconductor structure, and forming connection contact plugs penetrating the bonding insulating layer to connect the first semiconductor structure and the second semiconductor structure, at least one of the connection contact plugs being connected to the through-electrode.

According to embodiments of the present disclosure, it is possible to provide a memory device capable of achieving high integration using wafer bonding technology and a semiconductor package including the same.

The effects of the embodiments of the present disclosure are not limited to the effects mentioned above, and other effects not mentioned will be clearly understood by those skilled in the art from the description of the claims.

### BRIEF DESCRIPTION OF THE DRAWINGS

The present disclosure will be more fully understood from the detailed description and accompanying drawings provided below, which are provided for illustration only and are not intended to limit the present disclosure.

FIG. 1 illustrates an example of a plan view of a memory device according to embodiments of the present disclosure.

FIG. 2 illustrates an example of a cross-sectional structure of a semiconductor package according to embodiments of the present disclosure.

FIG. 3 illustrates an example of a cross-sectional structure of a memory device included in the semiconductor package of FIG. 2 in detail.

FIG. 4 is an enlarged drawing of a portion of FIG. 3.

FIG. 5 illustrates another example of a cross-sectional structure of a memory device included in the semiconductor package of FIG. 2 in detail.

FIG. 6 schematically illustrates another example of a cross-sectional structure of a semiconductor package according to embodiments of the present disclosure in detail.

FIG. 7 illustrates an example of a cross-sectional structure of a memory device included in the semiconductor package of FIG. 6 in detail.

FIGS. 8 to 25 illustrate examples of a manufacturing method of a memory device according to embodiments of the present disclosure.

### DETAILED DESCRIPTION

Hereinafter, embodiments of the present disclosure will be described in detail with reference to accompanying drawings. In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description, detailed descriptions of well-known functions and components incorporated herein will be omitted when it is determined that the description may make the subject matter unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, etc., are mentioned, it should be considered that numerical values for described elements or features, or corresponding information (e.g., level, range, etc.) include a tolerance or error range that may be caused by various factors (e.g., process factors, internal or external impact, noise, etc.) including in instances in which a relevant description is not specified.

Hereinafter, various embodiments of the disclosure will be described in detail with reference to the accompanying drawings.

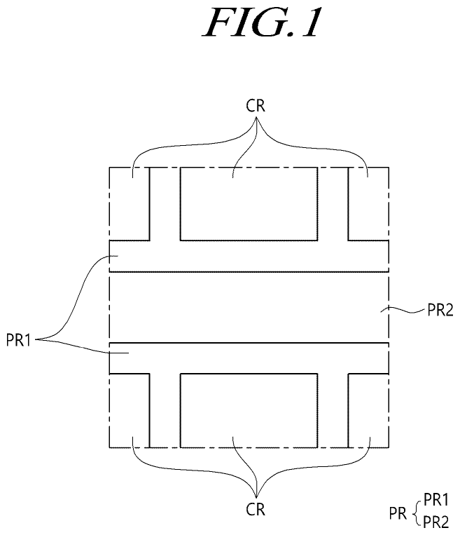

FIG. 1 illustrates an example of a plan view of a memory device according to embodiments of the present disclosure. It is noted that FIG. 1 merely shows a planar structure corresponding to a part of the memory device.

Referring to FIG. 1, the memory device may include a cell region CR and a peripheral region PR. The peripheral region PR may include, for example, a first peripheral region PR1 and a second peripheral region PR2. Memory cells may be disposed in the cell region CR. Peripheral circuits for transmitting various signals and voltages to the memory cells may be disposed in the peripheral region PR. For example, if the memory device is a dynamic random access memory (DRAM), a sub word line driver and a sense amplifier among the peripheral circuits may be disposed in the first peripheral region PR1. The remaining peripheral circuits except for the sub word line driver and the sense amplifier may be arranged in the second peripheral region PR2. The first peripheral region PR1 may surround the cell region CR. The second peripheral region PR2 may be disposed around the first peripheral region PR1.

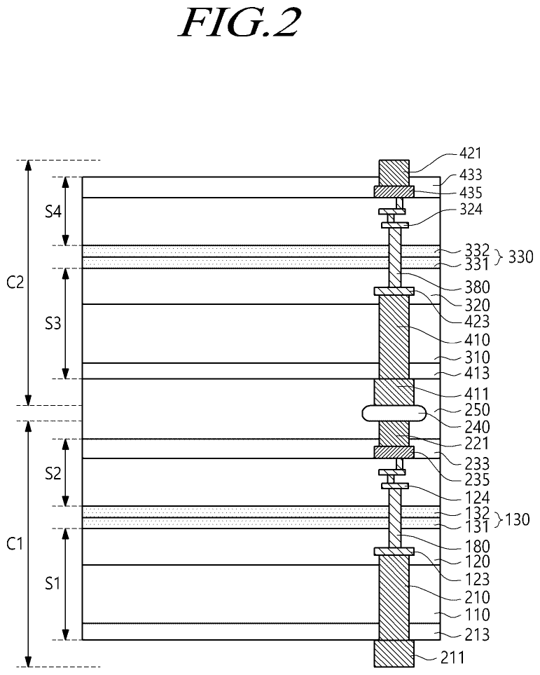

FIG. 2 illustrates an example of a cross-sectional structure of a semiconductor package according to embodiments of the present disclosure.

Referring to FIG. 2, a semiconductor package according to embodiments of the present disclosure may include a first semiconductor chip C1, a second semiconductor chip C2, a solder layer 240, and an encapsulation layer 250.

The first semiconductor chip C1 may include a first semiconductor structure S1, a second semiconductor structure S2, a first bonding insulating layer 130, a first front bonding pad 221, a first back insulating layer 213, and a first back bonding pad 211. The second semiconductor chip C2 may include a third semiconductor structure S3, a fourth semiconductor structure S4, a second bonding insulating layer 330, a second front bonding pad 421, a second back insulating layer 413, and a second back bonding pad 411.

The first semiconductor structure S1 may include a first substrate 110, a first lower insulating layer 120, a first through-electrode 210, and a first lower wiring 123. The second semiconductor structure S2 may include a first upper wiring 124, a first protective insulating layer 233, and a first chip pad 235. The third semiconductor structure S3 may include a second lower insulating layer 320, a second through-electrode 410, and a second lower wiring 423. The fourth semiconductor structure S4 may include a second upper wiring 324, a second protective insulating layer 433, and a second chip pad 435. The first bonding insulating layer 130 may include a first lower bonding insulating layer 131 and a first upper bonding insulating layer 132. The second bonding insulating layer 330 may include a second lower bonding insulating layer 331 and a second upper bonding insulating layer 332.

The first through-electrode 210 may penetrate the first substrate 110 and may be connected to the first lower wiring 123. One side of a first connection contact plug 180 is connected to the first lower wiring 123. The other side of the first connection contact plug 180 may be connected to the first upper wiring 124. The first connection contact plug 180 penetrates the first bonding insulating layer 130 and connects the first semiconductor structure S1 and the second semiconductor structure S2. The first upper wiring 124 may be connected to the first chip pad 235. The first chip pad 235 may be connected to the first front pad 221. The first back pad 211 may be connected to one side of the first through-electrode 210. In one embodiment, the first back pad 211 may be connected to the first front pad 221 through the first through-electrode 210, the first lower wiring 123, the first connection contact plug 180, the first upper wiring 124, and the first chip pad 235.

The second through-electrode 410 is connected to the second lower wiring 423 by passing through the second substrate 310. One side of a second connection contact plug 380 is connected to the second lower wiring 423. The other side of the second connection contact plug 380 is connected to the second upper wiring 324. The second connection contact plug 380 connects the third semiconductor structure S3 and the fourth semiconductor structure S4 by penetrating the second bonding insulating layer 330. The second upper wiring 324 may be connected to the second chip pad 435. The second chip pad 435 may be connected to the second front pad 421. The second back pad 411 is connected to one side of the second through-electrode 410. In one embodiment, the second back pad 411 may be connected to the second front pad 421 through the second through-electrode 410, the second lower wiring 423, the second connection contact plug 380, the second upper wiring 324, and the second chip pad 435.

The solder layer 240 may be disposed between the first front pad 221 and the second back pad 411. The solder layer 240 may connect the first front pad 221 and the second back pad 411. The solder layer 240 may include copper (Cu), nickel (Ni), tin (Sn), silver (Ag), or a combination thereof. The encapsulation layer 250 may be disposed between the second semiconductor structure S2 and the third semiconductor structure S3. The encapsulation layer 250 surrounds the first front pad 221, the solder layer 240, and the second back pad 411. The encapsulation layer 250 may include an epoxy molding compound.

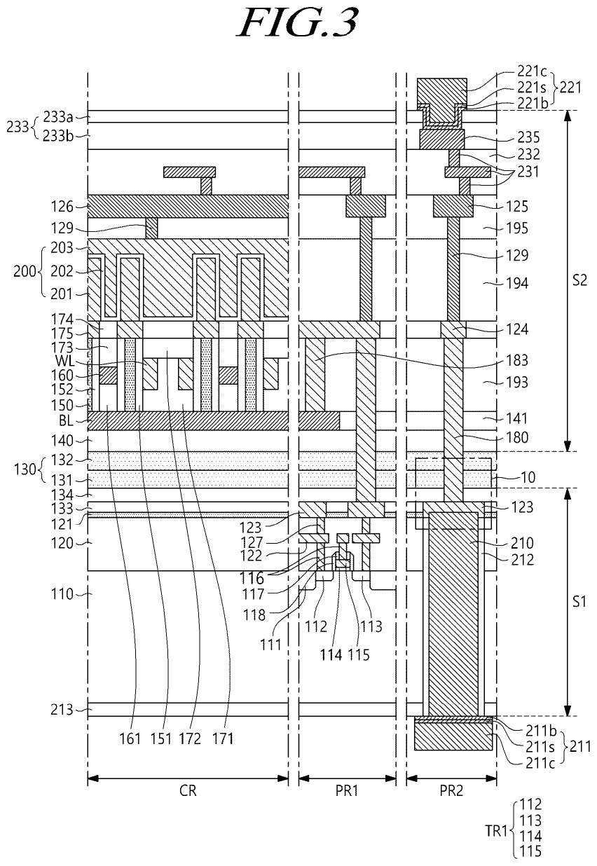

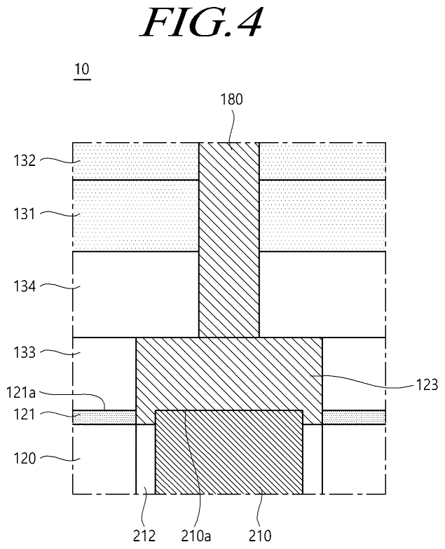

FIG. 3 illustrates an example of a cross-sectional structure of a memory device included in the semiconductor package of FIG. 2 in detail. FIG. 4 is an enlarged drawing of a portion 10 of FIG. 3.

FIG. 3 illustrates in detail the cross-sectional structure of the first semiconductor chip C1 of the semiconductor package of FIG. 2. A memory device may correspond to one semiconductor chip.

Referring to FIG. 3, the first semiconductor structure S1 may include a first substrate 110, a device isolation layer 111, a lower transistor TR1, a first gate capping layer 117, a first spacer 118, a first lower insulating layer 120, a first wiring 122, a first lower wiring 123, a first contact 116, a second contact 127, a capping insulating layer 121, a third insulating layer 133, and a fourth insulating layer 134.

The second semiconductor structure S2 may include a first upper insulating layer 140, a bit line BL, an interlayer insulating layer 141, an active layer 150, a second gate insulating layer 151, a third gate insulating layer 152, a back gate electrode 160, a second gate capping layer 161, a first insulating pattern 171, a second insulating pattern 172, a third insulating pattern 173, a fourth insulating pattern 174, a word line WL, a fifth insulating layer 193, a bit line connection contact 183, a first connection contact plug 180, a landing pad 175, a first upper wiring 124, a capacitor 200, a sixth insulating layer 194, a seventh insulating layer 195, a third contact 129, a second wiring 125, a third wiring 126, a circuit insulating layer 232, vertical/horizontal wirings 231, a first lower protective insulating layer 233b, a first upper protective insulating layer 233a, a first chip pad 235, and a first front pad 221. The lower transistor TR1 may include a source region 112, a drain region 113, a first gate insulating layer 114, and a gate electrode 115.

The first substrate 110 may include a semiconductor substrate such as a silicon wafer or a silicon-on-insulator (SOI) wafer. The first substrate 110 may include a III-V group semiconductor substrate, for example, a compound semiconductor substrate such as GaAs. The first substrate 110 may include single crystal silicon, polysilicon, amorphous silicon, single crystal silicon germanium, polycrystalline silicon germanium, carbon-doped silicon, or a combination thereof.

The first substrate 110 may include a cell region CR and a peripheral region PR. As described above with reference to FIG. 1, the peripheral region PR may include a first peripheral region PR1 and a second peripheral region PR2.

In the first peripheral region PR1, at least one device isolation layer 111 is disposed within the first substrate 110. The device isolation layer 111 may be formed using a trench device isolation technology such as shallow trench isolation (STI). The at least one device isolation layer 111 may include silicon oxide, silicon nitride, silicon oxynitride, low-K dielectrics, high-K dielectrics, or a combination thereof.

The first lower insulating layer 120 is disposed on the first substrate 110. The lower transistor TR1 is disposed on the first substrate 110. In one embodiment, the lower transistor TR1 may be one of the transistors included in the peripheral circuit. For example, the lower transistor TR1 may be one transistor included in a sub word line driver or a sense amplifier. The gate capping layer 117 is disposed on the gate electrode 115 of the lower transistor TR1. The first spacer 118 is disposed on the side surface of the first gate insulating layer 114, the gate electrode 115, and the gate capping layer 117.

The first contact 116 may be connected to the source region 112 and the drain region 113 of the lower transistor TR1 formed in the first substrate 110. The first wiring 122 is connected to the first contact 116. The second contact 127 is connected to the first wiring 122.

The capping insulating layer 121 and the third insulating layer 133 may be sequentially disposed on the second contact 127. The first lower wiring 123 penetrates the capping insulating layer 121 and the third insulating layer 133 and is connected to the second contact 127. In one embodiment, a lower surface of the first lower wiring 123 may form substantially the same plane as a lower surface of the capping insulating layer 121. The fourth insulating layer 134 is disposed on the third insulating layer 133 and the first lower wiring 123. The first lower wiring 123 may be connected to the source region 112 and the drain region 113 of the lower transistor TR1 through the second contact 127, the first wiring 122, and the first contact 116.

The first gate insulating layer 114, the gate capping layer 117, the first spacer 118, the first lower insulating layer 120, the capping insulating layer 121, the third insulating layer 133, and the fourth insulating layer 134 may include silicon oxide, silicon nitride, silicon oxynitride, a high-k dielectric, or a combination thereof. The gate electrode 115, the first contact 116, the second contact 127, the first wiring 122, and the first lower wiring 123 may include a conductive material such as a metal, a metal oxide, a metal nitride, a metal silicide, polysilicon, conductive carbon, or a combination thereof. The first bonding insulating layer 130 may include silicon oxide, silicon nitride, silicon oxynitride, silicon carbon nitride, a high-k dielectric, or a combination thereof. In one embodiment, the capping insulating layer 121 may include silicon nitride.

The second spacer 212 and the first through-electrode 210 may be disposed in the second peripheral region PR2. The second spacer 212 may surround the side surface of the first through-electrode 210. The second spacer 212 and the first through-electrode 210 penetrate the capping insulating layer 121, the first lower insulating layer 120, and the first substrate 11. One side of the first through-electrode 210 may be connected to the first lower wiring 123.

Referring to FIGS. 3 and 4, the upper surface 210a of the first through-electrode 210 may be positioned higher than the upper surface of the second spacer 212. The first lower wiring 123 may contact the side surface and the upper surface 210a of the first through-electrode 210. In one embodiment, the upper surface 210 a of the first through-electrode 210 may be substantially the same plane as the upper surface 121a of the capping insulating layer 121.

The first through-electrode 210 may include a conductive material, such as a metal, a metal oxide, a metal nitride, a metal silicide, polysilicon, conductive carbon, or a combination thereof. In one embodiment, the first through-electrode 210 may include titanium (Ti), titanium nitride (TiN), tantalum (Ta), tantalum nitride (TaN), copper (Cu), or a combination thereof.

The first lower bonding insulating layer 131 is disposed on the first semiconductor structure S1. The first lower bonding insulating layer 131 is disposed between the first semiconductor structure S1 and the second semiconductor structure S2. The first upper bonding insulating layer 132 is disposed under the second semiconductor structure S2. The first upper bonding insulating layer 132 is disposed between the first lower bonding insulating layer 131 and the second semiconductor structure S2. In one embodiment, the upper surface of the first lower bonding insulating layer 131 and the lower surface of the first upper bonding insulating layer 132 may form substantially the same plane.

The second semiconductor structure S2 may be disposed on the first upper bonding insulating layer 132. The second semiconductor structure S2 may be bonded to the first semiconductor structure S1 through the first bonding insulating layer 130.

The first upper insulating layer 140 is disposed on the first upper bonding insulating layer 132. The bit line BL is disposed on the first upper insulating layer 140. The bit line BL may extend from the cell region CR to the first peripheral region PR1. The first upper insulating layer 140 may include silicon oxide, silicon nitride, silicon oxynitride, silicon carbonitride, a high-k dielectric, or a combination thereof. The bit line BL may include a conductive material, such as a metal, a metal nitride, a metal silicide, polysilicon, a conductive carbon, or a combination thereof. The first lower bonding insulating layer 131 and the first upper bonding insulating layer 132 may include silicon nitride.

A memory cell may be disposed on the bit line BL in the cell region CR. In one embodiment, the memory cell may include one transistor and one capacitor. Hereinafter, it will be described an example in which the memory cell includes one transistor and one capacitor.

The active layer 150 may contact the bit line BL and extend in the vertical direction. The active layer 150 may include a channel region formed in an area overlapping the word line WL or the back gate electrode 160. The active layer 150 may include a source or drain region formed around the channel region. The active layer 150 may include polysilicon or single crystal silicon.

The second gate insulating layer 151 and the third gate insulating layer 152 are disposed on a side surface of the active layer 150. The second gate insulating layer 151 is disposed between the active layer 150 and the word line WL. The second gate insulating layer 151 may extend in the vertical direction. The third gate insulating layer 152 is disposed between the active layer 150 and the back gate electrode 160. The third gate insulating layer 152 extends in the vertical direction. The second gate insulating layer 151 and the third gate insulating layer 152 may include silicon oxide, silicon nitride, silicon oxynitride, silicon carbonitride, a high-k dielectric material, or a combination thereof.

The word line WL, the first insulating pattern 171, and the second insulating pattern 172) are arranged between the facing second gate insulating layers 151 (shown on either side of these elements). The vertical length of the word line WL may be smaller than the vertical length of the active layer 150. The first insulating pattern 171 is positioned between the facing word lines WL. The first insulating pattern 171 may cover one side surface and a lower surface of the word line WL. The second insulating pattern 172 may cover the upper surface of the first insulating pattern 171 and the word line WL.

The back gate electrode 160, the second gate capping layer 161, and the third insulating pattern 173 are arranged between the facing third gate insulating layers 152 (shown on either side of these elements). The vertical length of the back gate electrode 160 may be smaller than the vertical length of the active layer 150. The second gate capping layer 161 is disposed between the back gate electrode 160 and the bit line BL. The third insulating pattern 173 is disposed on the back gate electrode 160. The second gate capping layer 161, the back gate electrode 160, and the third insulating pattern 173 overlap with each other in the vertical direction.

The word line WL and the back gate electrode 160 may include a conductive material such as a metal, a metal nitride, a metal silicide, polysilicon, conductive carbon, or a combination thereof. The first insulating pattern 171, the second insulating pattern 172, the third insulating pattern 173, the fourth insulating pattern 174, and the second gate capping layer 161 may include silicon oxide, silicon nitride, silicon oxynitride, silicon carbonitride, a high-k dielectric, or a combination thereof.

The fourth insulating pattern 174 and the landing pad 175 are arranged on the active layer 150, the second and third gate insulating layers 151 and 152, the second insulating pattern 172, and the third insulating pattern 173. The landing pad 175 corresponds to one active layer 150. The landing pad 175 contacts the upper surface of the corresponding active layer 150. The fourth insulating pattern 174 is arranged between the landing pads 175. The landing pad 175 may include a conductive material such as a metal, a metal nitride, a metal silicide, polysilicon, a conductive carbon, or a combination thereof. The fourth insulating pattern 174 may include silicon oxide, silicon nitride, silicon oxynitride, silicon carbon nitride, a high-k dielectric, or a combination thereof.

The bit line connection contact 183 is arranged on a bit line BL in the first peripheral region PR1. The first upper wiring 124 and the fourth insulating pattern 174 are arranged on the bit line connection contact 183. One side of the bit line connection contact 183 contacts an upper surface of the bit line BL. The other side of the bit line connection contact 183 contacts the first upper wiring 124.

In the first peripheral region PR1 and the second peripheral region PR2, one side of the first connection contact plug 180 is connected to the first lower wiring 123. The other side of the first connection contact plug 180 is connected to the first upper wiring 124. The first connection contact plug 180 extends vertically from the upper surface of the first lower wiring 123, and penetrates the first lower bonding insulating layer 131, the first upper bonding insulating layer 132, the first upper insulating layer 140, the interlayer insulating layer 141, and the fifth insulating layer 193 to contact the lower surface of the first upper wiring 124.

In the first peripheral region PR1, the bit line BL may be connected to the first lower wiring 123 through the bit line connection contact 183, the first upper wiring 124, and the first connection contact plug 180. The first lower wiring 123 may be connected to the lower transistor TR1 through the second contact 127, the first wiring 122, and the first contact 116. The bit line connection contact 183, the third wiring 124, and the first connection contact plug 180 may include a conductive material such as a metal, a metal oxide, a metal nitride, a metal silicide, polysilicon, conductive carbon, or a combination thereof.

In the second peripheral region PR2, the first through-electrode 210 may be connected to the first upper wiring 124 through the first lower wiring 123 and the first connection contact plug 180.

In the cell region CR, a capacitor 200 is arranged on the fourth insulating pattern 174 and the landing pad 175. A lower electrode 201 of the capacitor 200 may correspond to one landing pad 175. The lower electrode 201 contacts the upper surface of the landing pad 175. A dielectric layer 202 may be disposed to cover the side surface and the upper surface of the lower electrode 201 and the upper surface of the fourth insulating pattern 174. In one embodiment, the dielectric layer 202 may conformally cover the side surface and the upper surface of the lower electrode 201. An upper electrode 203 may be disposed on the dielectric layer 202. The lower electrode 201 and the upper electrode 203 may include a conductive material such as a metal, a metal oxide, a metal nitride, a metal silicide, polysilicon, a conductive carbon, or a combination thereof. The dielectric layer 202 may include a high-k dielectric material, silicon oxide, silicon nitride, or a combination thereof.

The seventh insulating layer 195 is disposed on the upper electrode 203. The third contact 129 penetrates the seventh insulating layer 195 and is connected to the upper electrode 203. The third wiring 126 is disposed on the seventh insulating layer 195.

The sixth insulating layer 194 and the seventh insulating layer 195 are arranged on the first upper wiring 124 and the fourth insulating pattern 174 in the first peripheral region PR1 and the second peripheral region PR2. The third contact 129 penetrates the sixth insulating layer 194 and the seventh insulating layer 195, and is connected to at least one first upper wiring 124. The fifth insulating layer 195 is disposed on the fourth insulating layer 194. The second wiring 125 is disposed on the third contact 129.

The circuit insulating layer 232 is disposed on the second wiring 125 and the third wiring 126. The vertical/horizontal wirings 231 are disposed within the circuit insulating layer 232. At least one of the vertical/horizontal wirings 231 is connected to the second wiring 125. The first protective insulating layer 233 is disposed on the circuit insulating layer 232. The first protective insulating layer 233 may include a first lower protective insulating layer 233b and a first upper protective insulating layer 233a. The first chip pad 235 is disposed within the first protective insulating layer 233.

The first front pad 221 is connected on the first chip pad 235. The first front pad 221 is connected to the vertical/horizontal wirings 231 through the first chip pad 235. The first front pad 221 may include a first front barrier layer 221b, a first front seed layer 221s, and a first front conductive layer 221c.

The first front barrier layer 221b may include titanium (Ti), titanium tungsten (TiW), titanium nitride (TiN), tantalum (Ta), tantalum nitride (TaN), or a combination thereof. The first front seed layer 221s may include copper. The first front conductive layer 221c may include copper (Cu), tungsten (W), tungsten nitride (WN), titanium (Ti), titanium tungsten (TiW), titanium nitride (TiN), tantalum (Ta), tantalum nitride (TaN), cobalt (Co), nickel (Ni), silver (Ag), platinum (Pt), ruthenium (Ru), gold (Au), aluminum (Al), tin (Sn), or a combination thereof. The first chip pad 235 may include aluminum. The vertical/horizontal wirings 231 may include a conductive material such as a metal, a metal oxide, a metal nitride, a metal silicide, polysilicon, a conductive carbon, or a combination thereof.

The first back insulating layer 213 is disposed under the first substrate 110. In the second peripheral region PR2, the first through-electrode 210 penetrates the first substrate 110 and the first back insulating layer 213, and is connected to a first back pad 211.

The first back pad 211 may include a first back barrier layer 211b, a first back seed layer 211s, and a first back conductive layer 211c. The first back barrier layer 211b may include titanium (Ti), titanium tungsten (TiW), titanium nitride (TiN), tantalum (Ta), tantalum nitride (TaN), or a combination thereof. The first back seed layer 211s may include copper. The first back conductive layer 211c may include copper (Cu), tungsten (W), tungsten nitride (WN), titanium (Ti), titanium tungsten (TiW), titanium nitride (TiN), tantalum (Ta), tantalum nitride (TaN), cobalt (Co), nickel (Ni), silver (Ag), platinum (Pt), ruthenium (Ru), gold (Au), aluminum (Al), tin (Sn), or a combination thereof.

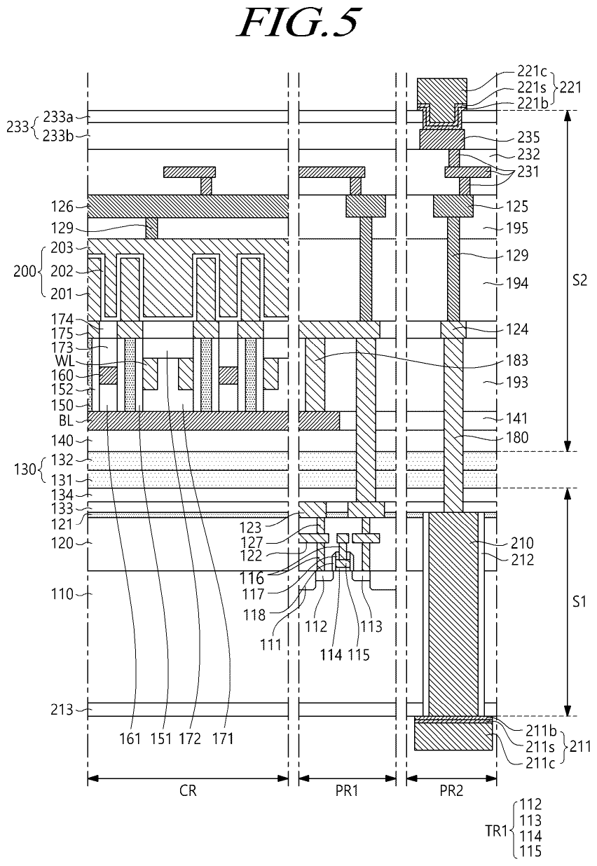

FIG. 5 illustrates another example of a cross-sectional structure of a memory device included in the semiconductor package of FIG. 2 in detail.

FIG. 5 is a drawing illustrating in detail the cross-sectional structure of the first semiconductor chip C1 of the semiconductor package of FIG. 2. A memory device may correspond to one semiconductor chip.

Referring to FIG. 5, in one embodiment, the first lower wiring 123 in the second peripheral region PR2 may not be disposed on the first through-electrode 210. In the second peripheral region PR2, the first connection contact plug 180 may penetrate the third insulating layer 133, and be directly connected to the first through-electrode 210. The upper surface of the first through-electrode 210 may form substantially the same plane as the upper surface of the second spacer 212. Except for the fact that the first connection contact plug 180 is directly connected to the first through-electrode 210, the memory device illustrated in FIG. 5 may be substantially the same as the memory device illustrated in FIG. 3.

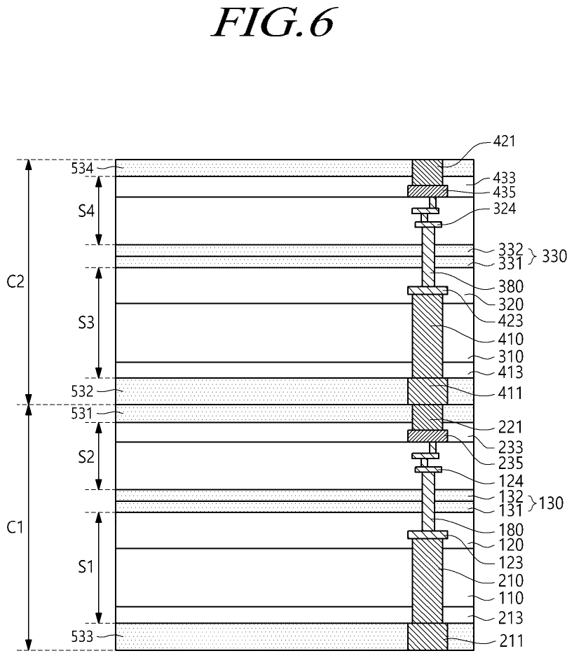

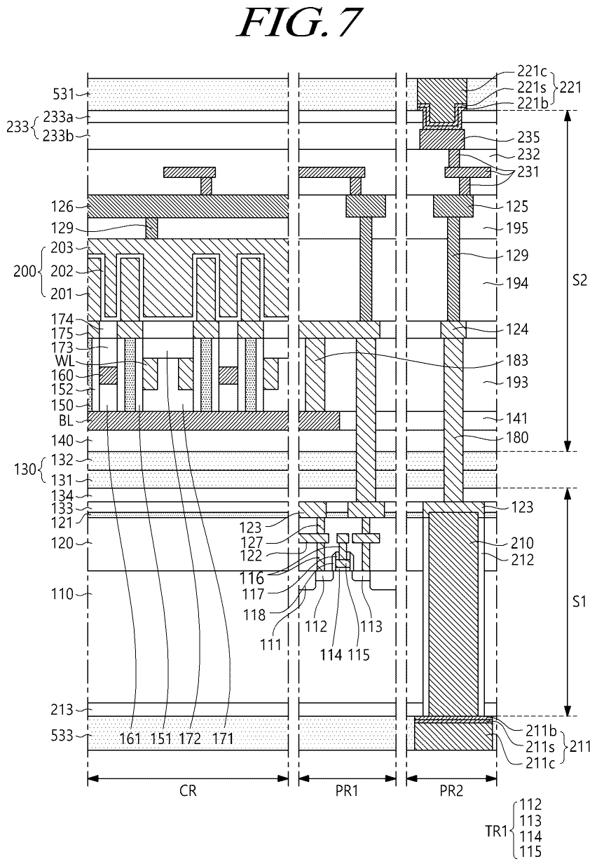

FIG. 6 schematically illustrates another example of a cross-sectional structure of a semiconductor package according to embodiments of the present disclosure in detail. FIG. 7 illustrates an example of a cross-sectional structure of a memory device included in the semiconductor package of FIG. 6 in detail.

FIG. 7 is a drawing showing in detail the cross-sectional structure of the first semiconductor chip C1 among the semiconductor packages of FIG. 6. The memory device may correspond to one semiconductor chip.

Referring to FIG. 6 and FIG. 7, a first back bonding insulating layer 533 may be disposed on the lower surface of the first semiconductor chip C1 illustrated in FIG. 3, and a first front bonding insulating layer 531 may be further disposed on the upper surface of the first semiconductor chip C1. Similarly, a second back bonding insulating layer 532 may be disposed on the lower surface of the second semiconductor chip C2 illustrated in FIG. 3, and a second front bonding insulating layer 534 may be further disposed on the upper surface of the second semiconductor chip C2. One surface of the first semiconductor chip C1 and one surface of the second semiconductor chip C2 may be directly bonded. The first front bonding insulating layer 531 is bonded to the second back bonding insulating layer 532.

In one embodiment, the first front bonding insulating layer 531, the first back bonding insulating layer 533, the second front bonding insulating layer 534, and the second back bonding insulating layer 532 may include the same material as the first bonding insulating layer 130.

In one embodiment, the lower surface of the first back bonding insulating layer 533 may form a substantially coplanar plane with the lower surface of the first back pad 211. The upper surface of the first front bonding insulating layer 531 may form a substantially coplanar plane with the upper surface of the first front pad 221.

The upper surface of the first front bonding insulating layer 531 may directly contact the lower surface of the second back bonding insulating layer 532. The upper surface of the first front pad 221 may directly contact the lower surface of the second back pad 411.

In one embodiment, the gap between the third semiconductor structure S3 and the second semiconductor structure S2 may be smaller than the gap between the third semiconductor structure S3 and the second semiconductor structure S2 described with reference to FIG. 3.

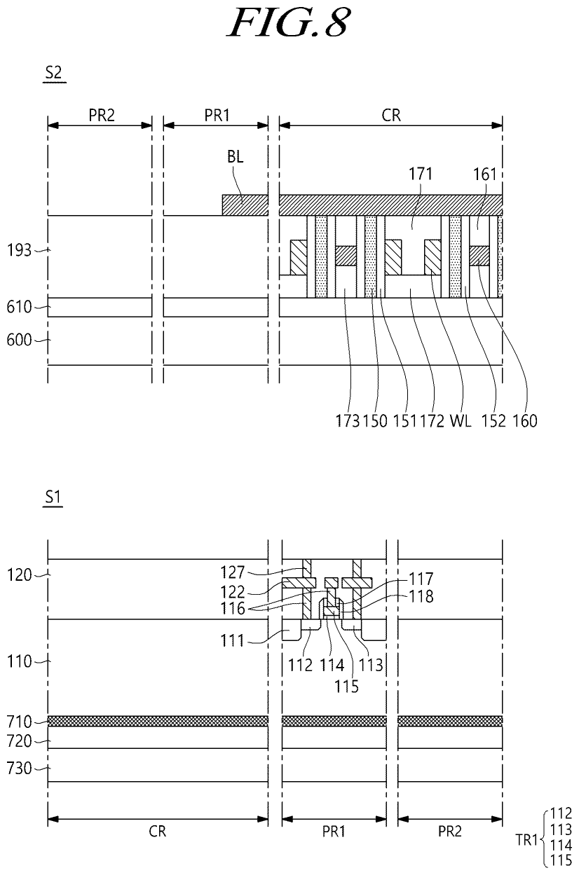

FIGS. 8 to 25 illustrate examples of a manufacturing method of a memory device according to embodiments of the present disclosure.

Referring to FIG. 8, a first semiconductor structure S1 and a second semiconductor structure S2 are prepared. The first semiconductor structure S1 and the second semiconductor structure S2 may be different wafers.

The first semiconductor structure S1 may include a base substrate 730, a base insulating layer 720, a semiconductor layer 710, a first substrate 110, a device isolation layer 111, a lower transistor TR1, a first contact 116, a first wiring 122, a second contact 127, and a first lower insulating layer 120.

In one embodiment, the base substrate 730 and the base insulating layer 720 may form a semiconductor substrate such as a Silicon-On-Insulator (SOI) wafer. The base substrate 730 may include a III-V group semiconductor substrate, for example, a compound semiconductor substrate such as GaAs. The base substrate 730 may include single crystal silicon, polysilicon, amorphous silicon, single crystal silicon germanium, polycrystalline silicon germanium, carbon doped silicon, or a combination thereof. In one embodiment, the base insulating layer 720 may include silicon oxide.

In one embodiment, the semiconductor layer 710 may include silicon germanium. In one embodiment, the first substrate 110 may be a layer epitaxially grown from the semiconductor layer 710.

In another embodiment, the first semiconductor structure S1 may not include the semiconductor layer 710. In this case, the first substrate 110 may be formed on the base insulating layer 720. In this case, the first substrate 110 may be a layer epitaxially grown from the base insulating layer 720.

The second semiconductor structure S2 may include a third substrate 600, an eighth insulating layer 610, a fifth insulating layer 193, an active layer 150, a second gate insulating layer 151, a third gate insulating layer 152, a word line WL, a back gate electrode 160, a second gate capping layer 161, a first insulating pattern 171, a second insulating pattern 172, a third insulating pattern 173, and a bit line BL.

In one embodiment, the third substrate 600 and the eighth insulating layer 610 may form a semiconductor substrate such as a Silicon-On-Insulator (SOI) wafer. The third substrate 600 may include a III-V group semiconductor substrate, for example, a compound semiconductor substrate such as GaAs. The third substrate 600 may include single crystal silicon, polysilicon, amorphous silicon, single crystal silicon germanium, polycrystalline silicon germanium, carbon-doped silicon, or a combination thereof. In one embodiment, the eighth insulating layer 610 may include silicon oxide.

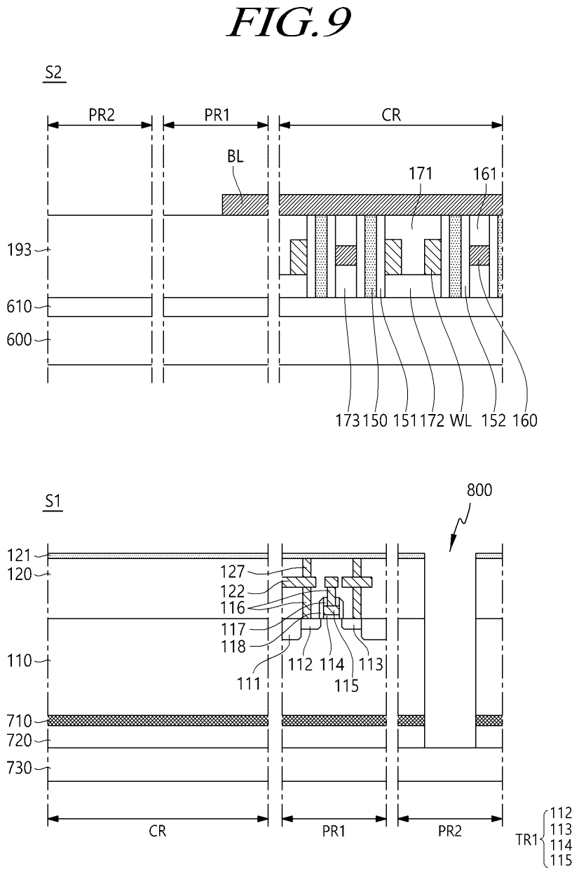

Referring to FIG. 9, a capping insulating layer 121 is formed on the first lower insulating layer 120 of the first semiconductor structure S1. In one embodiment, the capping insulating layer 121 may include silicon nitride.

A first through hole 800 may be formed in the second peripheral region PR2 through the capping insulating layer 121, the first lower insulating layer 120, the first substrate 110, the semiconductor layer 710, and the base insulating layer 720. An upper surface of the base substrate 730 may be exposed through the first through hole 800.

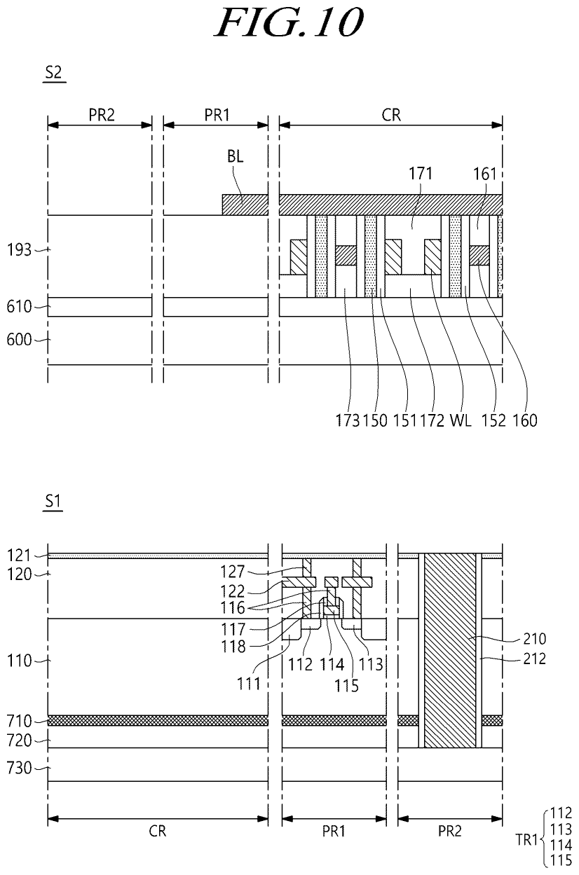

Referring to FIG. 10, a second spacer 212 is formed on the side surface of the first through hole 800 of FIG. 9. A first through-electrode 210 is formed in the space between the inner surfaces of the second spacer 212. The process of forming the first through-electrode 210 may include an etch back process. The upper surface of the second spacer 212 and the upper surface of the first through-electrode 210 may form substantially the same plane as the upper surface of the capping insulating layer 121.

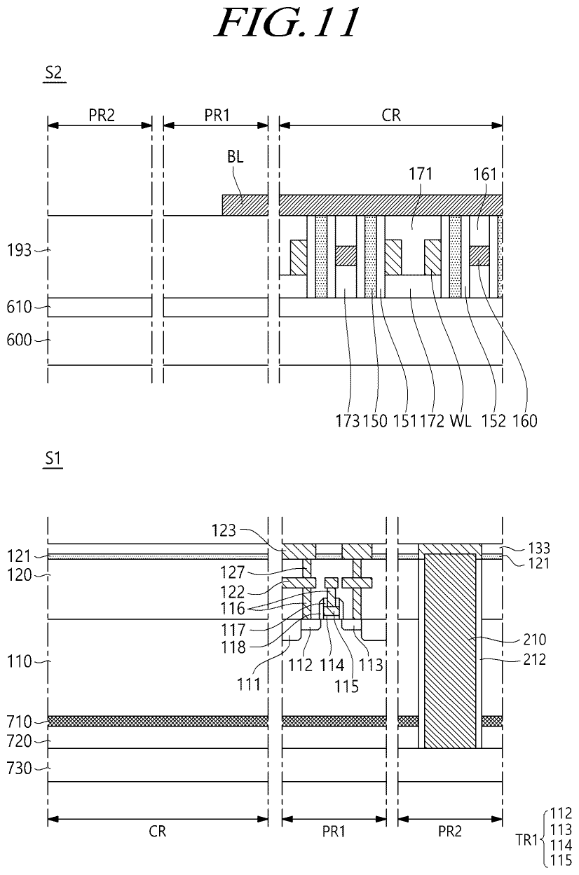

Referring to FIG. 11, a third insulating layer 133 is formed on the capping insulating layer 121. A first lower wiring 123 is formed that penetrates the third insulating layer 133 and the capping insulating layer 121 in the first peripheral region PR1 and the second peripheral region PR2.

In the first peripheral region PR1, the first lower wiring 123 is connected to the second contact 127. The upper surface of the first lower wiring 123 may form substantially the same plane as the upper surface of the third insulating layer 133.

In the second peripheral region PR2, the first lower wiring 123 may penetrate the third insulating layer 133 and a part of the capping insulating layer 121. The first lower wiring 123 may cover the upper surface and the side surface of the first through-electrode 210. At least a part of the first lower wiring 123 may be located between the side surface of the first through-electrode 210 and the capping insulating layer 121.

In one embodiment, the upper surface of the first through-electrode 210 may be located higher than the upper surface of the second spacer 212. In one embodiment, the upper surface of the first through-electrode 210 may be substantially on the same plane as the upper surface of the capping insulating layer 121.

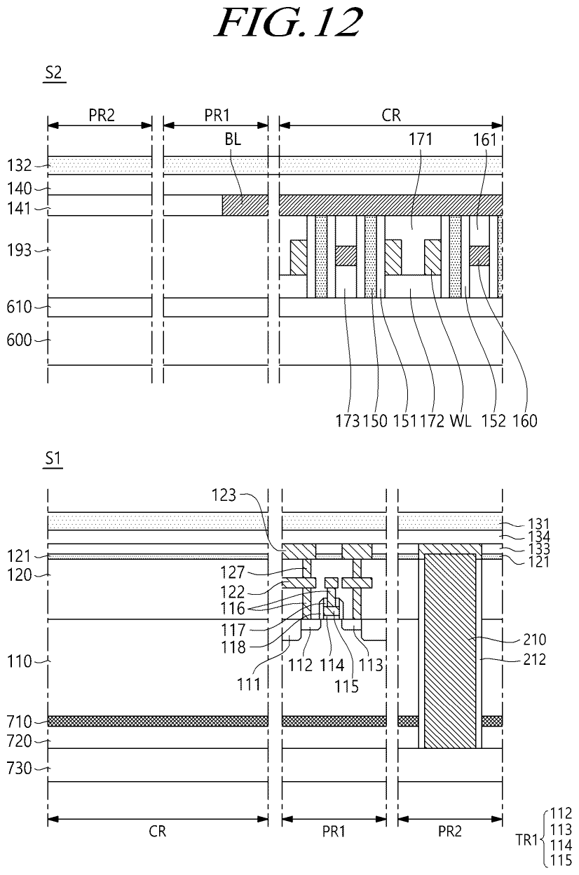

Referring to FIG. 12, a fourth insulating layer 134 is formed on the third insulating layer 133 of the first semiconductor structure S1. A first lower bonding insulating layer 131 is formed on the fourth insulating layer 134.

An interlayer insulating layer 141 is formed on the fifth insulating layer 193 of the second semiconductor structure S2. A first upper insulating layer 140 is formed on the interlayer insulating layer 141 and the bit line BL. A first upper bonding insulating layer 132 is formed on the first upper insulating layer 140.

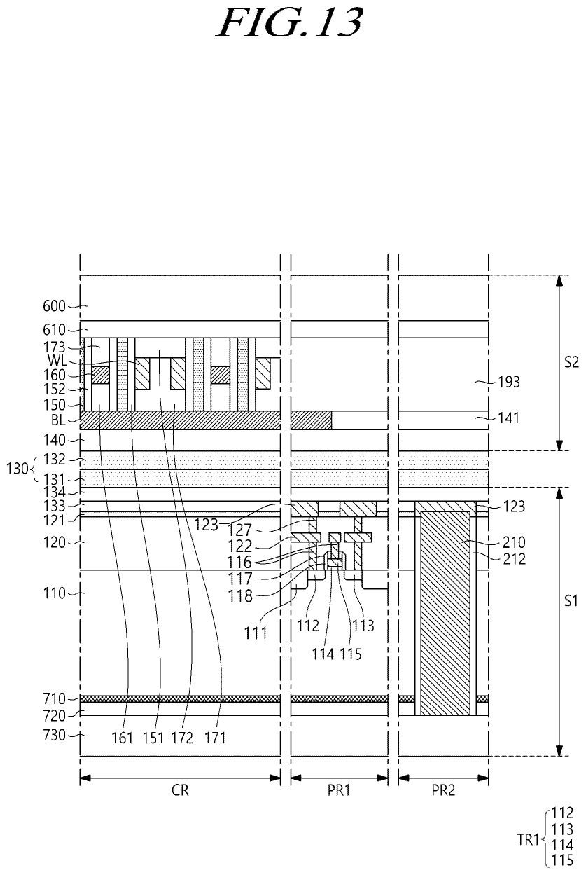

Referring to FIG. 13, a second semiconductor structure S2 is bonded on the first semiconductor structure S1. In one embodiment, a process of bonding the first semiconductor structure S1 and the second semiconductor structure S2 may include a process of contacting the first upper bonding insulating layer 132 with the upper surface of the first lower bonding insulating layer 131 and then applying heat.

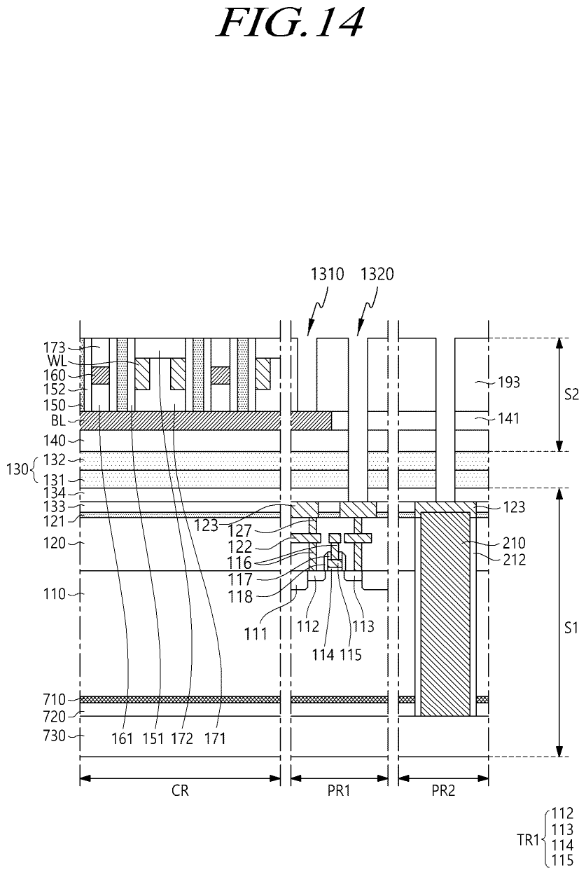

Referring to FIG. 14, the third substrate 600 and the eighth insulating layer 610 may be removed. In one embodiment, the third substrate 600 and the eighth insulating layer 610 may be removed using a laser. Alternatively, in another embodiment, the third substrate 600 may be removed through a grinding process or a chemical mechanical polishing (CMP) process, and the eighth insulating layer 610 may be removed through a wet-etching process.

A second through hole 1310 and a third through hole 1320 may be formed in the first peripheral region PR1. The process of forming the second through hole 1310 and the third through hole 1320 may include an etching process. The second through hole 1310 may penetrate the fifth insulating layer 193 to expose the upper surface of the bit line BL. The third through hole 1320 may penetrate the fifth insulating layer 193, the interlayer insulating layer 141, the first upper insulating layer 140, the bonding insulating layer 130, and the fourth insulating layer 134 to expose the upper surface of the first lower wiring 123.

The second through hole 1320 may also be formed in the second peripheral region PR2. The second through hole 1320 formed in the second peripheral region PR2 can expose the upper surface of the first lower wiring 123 connected to the first through-electrode 210.

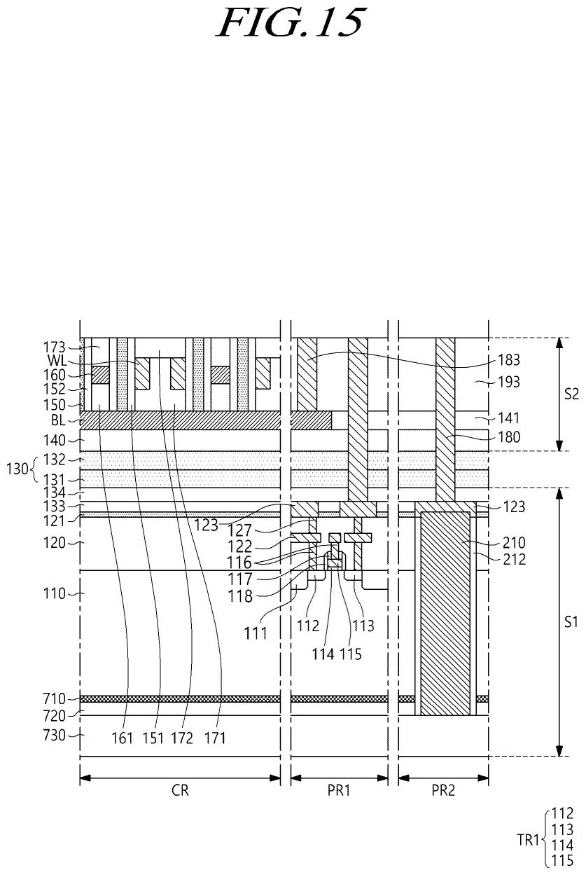

Referring to FIG. 15, a conductive material may be filled inside the second through hole 1310 and the third through hole 1320 of FIG. 14. A bit line connection contact 183 may be formed by filling the conductive material in the second through hole 1310. A first connection contact plug 180 may be formed by filling a conductive material in the third through hole 1320.

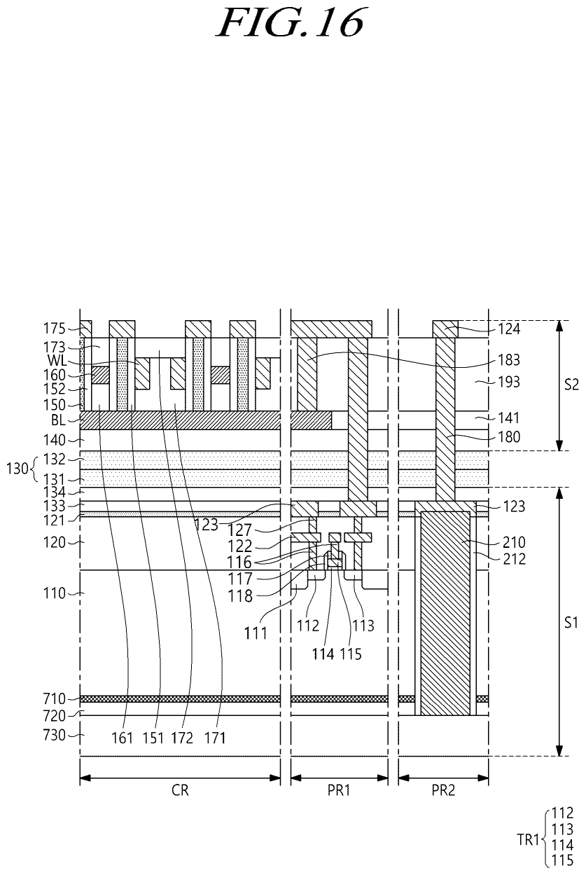

Referring to FIG. 16, a landing pad 175 is formed on the corresponding active layer 150 in the cell region CR. The lower surface of the landing pad 175 contacts the upper surface of the corresponding active layer 150. A first upper wiring 124 is formed in the first peripheral region PR1 and the second peripheral region PR2. The first upper wiring 124 is formed on the bit line connection contact 183 and the first connection contact plug 180.

In one embodiment, at least one first upper wiring 124 may connect the bit line connection contact 183 and the first connection contact plug 180. The bit line BL may be connected to the first lower wiring 123 through the bit line connection contact 183, at least one first upper wiring 124 connected to the bit line connection contact 183, and the first connection contact plug 180 connected to at least one first upper wiring 124. At least one first upper wiring 124 may be connected to the first through-electrode 210 via the first connection contact plug 180 and the first lower wiring 123.

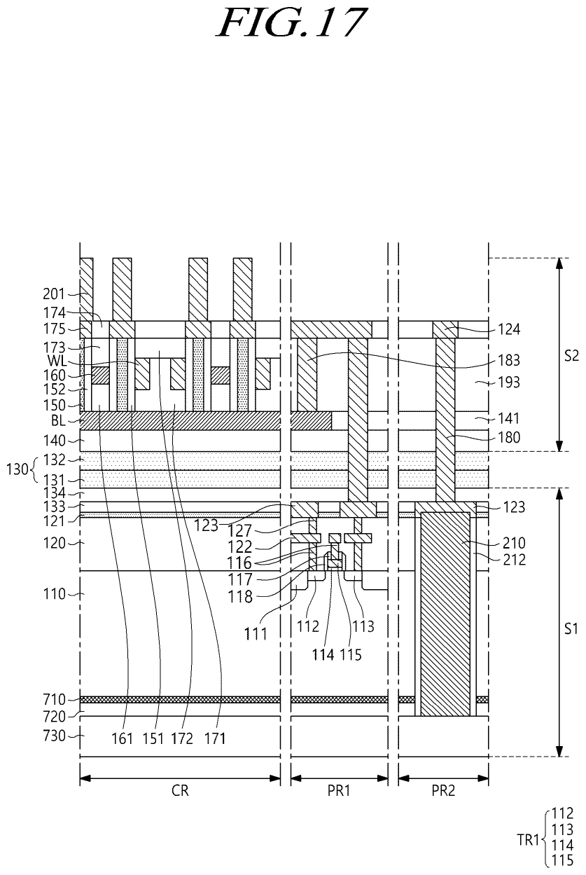

Referring to FIG. 17, a fourth insulating pattern 174 may be formed to cover the landing pad 175 and the first upper wiring 124. The fourth insulating pattern 174 may be located between the landing pads 175, and may be located between the first upper wirings 124.

After the fourth insulating pattern 174 is formed, a lower electrode 201 is formed on the landing pad 175 in the cell region CR. The lower electrode 201 may be formed on the upper surface of a corresponding landing pad 175. The lower surface of the lower electrode 201 contacts the upper surface of the landing pad 175.

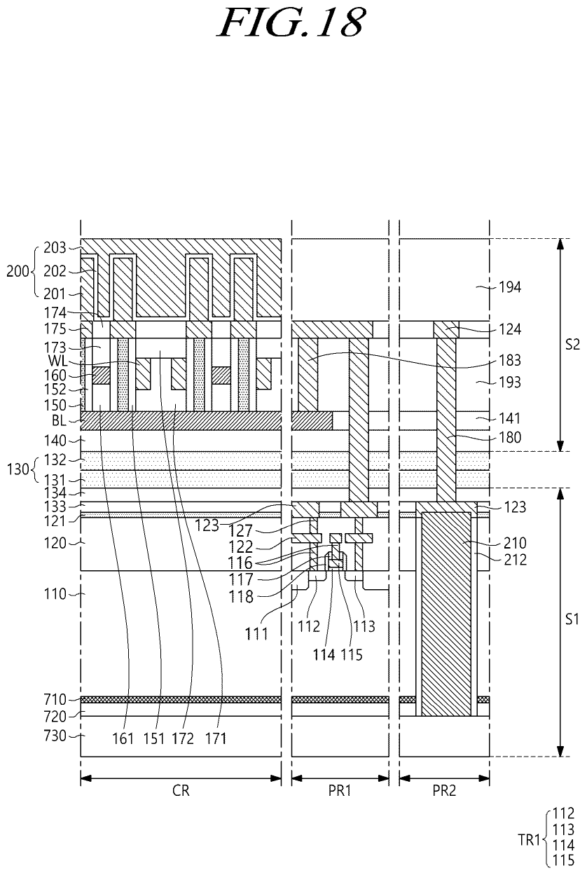

Referring to FIG. 18, a dielectric layer 202 is formed on the lower electrode 201 and the fourth insulating pattern 174 in the cell region CR. In one embodiment, the dielectric layer 202 may be conformally formed on the side surface and the upper surface of the lower electrode 201. The dielectric layer 202 covers the side surface and the upper surface of the lower electrode 201 and the upper surface of the fourth insulating pattern 174. The upper electrode 203 is formed on the dielectric layer 202. The dielectric layer 202 and the upper electrode 203 may not be disposed in the peripheral region PR. The sixth insulating layer 194 is formed in the peripheral region PR.

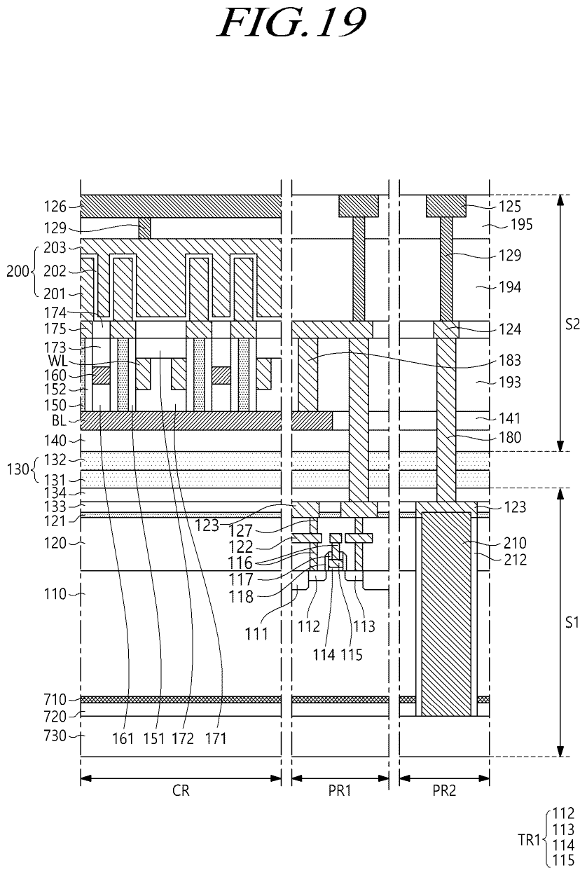

Referring to FIG. 19, a seventh insulating layer 195 is formed on the upper electrode 203 and the sixth insulating layer 194. After the seventh insulating layer 195 is formed, the third contact 129 penetrating the seventh insulating layer 195 is formed. In the cell region CR, the third contact 129 contacts the upper surface of the upper electrode 203. In the first peripheral region PR1 and the second peripheral region PR2, the third contact 129 contacts the upper surface of the first upper wiring 124.

In the cell region CR, a third wiring 126 may be formed on the third contact 129. In the first peripheral region PR1 and the second peripheral region PR2, a second wiring 125 is formed on the third contact 129. The second wiring 125 and the third wiring 126 may each be formed within the seventh insulating layer 195.

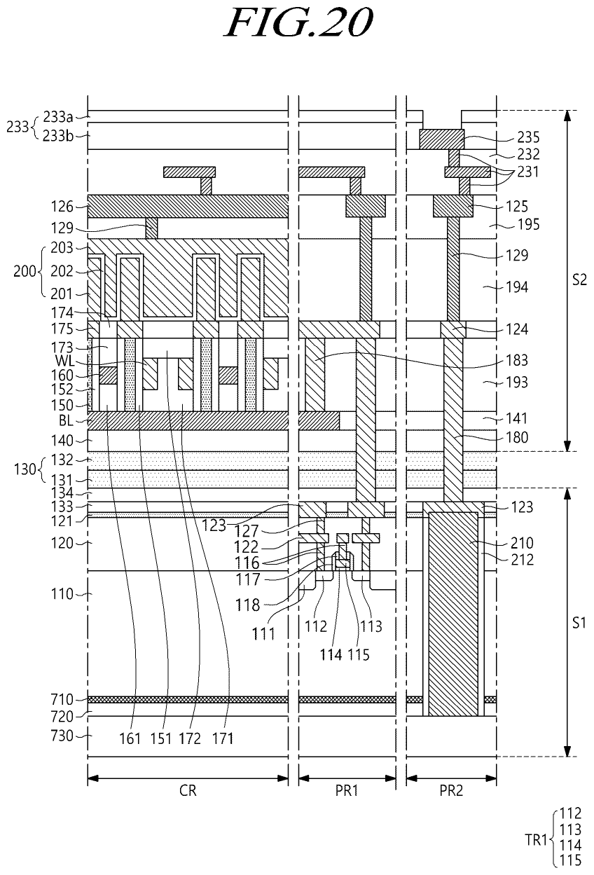

Referring to FIG. 20, a circuit insulating layer 232 is formed on the seventh insulating layer 195 and the third wiring 126. The circuit insulating layer 232 is illustrated as a single layer, but may be two or more multi-layers. A vertical/horizontal wiring 231 is formed within the circuit insulating layer 232. At least a portion of the vertical/horizontal wiring 231 may be connected to the second wiring 125.

A first protective insulating layer 233 is formed on the circuit insulating layer 231. The first protective insulating layer 233 includes a first lower protective insulating layer 233b and a first upper protective insulating layer 233a. A first chip pad 235 is formed within the first protective insulating layer 233. The first chip pad 235 may be connected to at least one vertical/horizontal wiring 231.

A portion of the first lower protective insulating layer 233b and the first upper protective insulating layer 233a may be removed so that at least a portion of the upper surface of the first chip pad 235 is exposed.

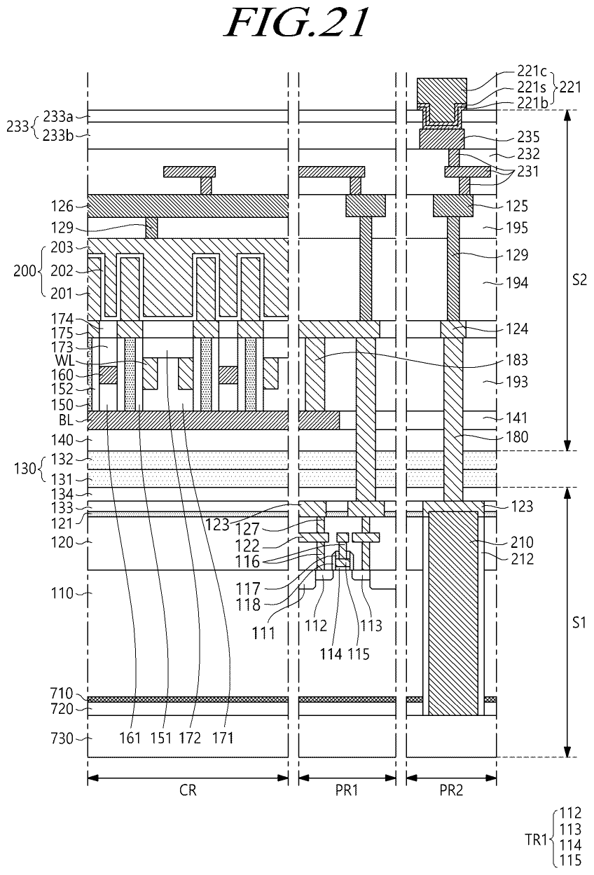

Referring to FIG. 21, a first front pad 221 is formed on the first chip pad 235 and the first protective insulating layer 233. The first front pad 221 is connected to the first chip pad 235. The first front pad 221 includes a first front barrier layer 221b, a first front seed layer 221s, and a first front conductive layer 221c. The first front barrier layer 221b contacts the upper surface of the first chip pad 235. The first front barrier layer 221b and the first front seed layer 221s may cover the side surface of the first protective insulating layer 233 and the lower surface of the first chip pad 235.

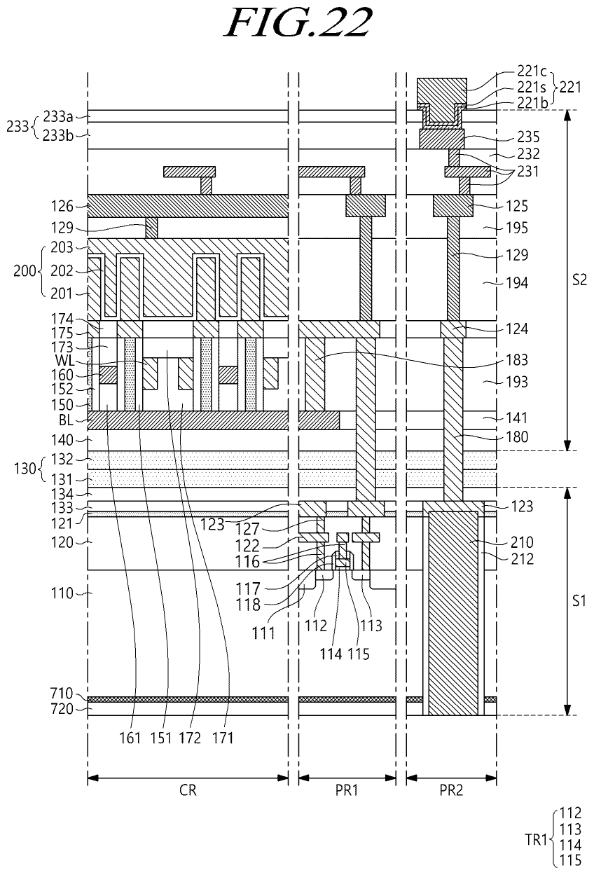

Referring to FIG. 22, the base substrate 730 may be removed. In one embodiment, the base substrate 730 may be removed using a laser. The base substrate 730 may be removed to expose one surface of the base insulating layer 720 and the first through-electrode 210.

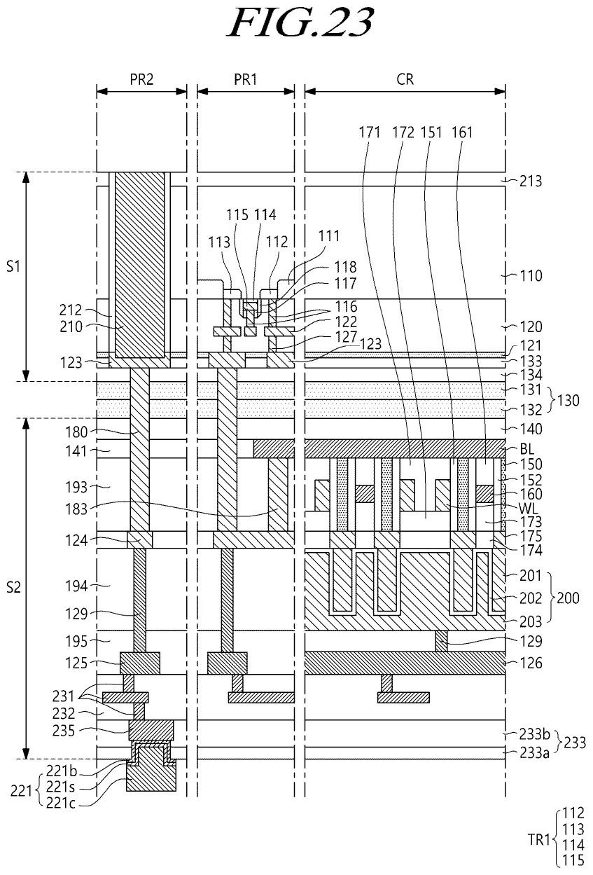

Referring to FIG. 23, the base insulating layer 720 and the semiconductor layer 710 may be removed. The process of removing the base insulating layer 720 and the semiconductor layer 710 may include a grinding process or a CMP process.

In the process of etching the semiconductor layer 710, at least a portion of the first substrate 110 may be removed together with the semiconductor layer 710. A first back insulating layer 213 is formed in a location where at least a portion of the first substrate 110 is removed. The first back insulating layer 213 may be formed to surround the first through-electrode 210 and the second spacer 212.

When the base insulating layer 720 and the semiconductor layer 710 are removed, at least a portion of the first through-electrode 210 may be removed together with the base insulating layer 720 and the semiconductor layer 710. One side (e.g., the upper side) of the first through-electrode 210 may form substantially the same plane as one side (e.g., the upper side) of the first back insulating layer 213.

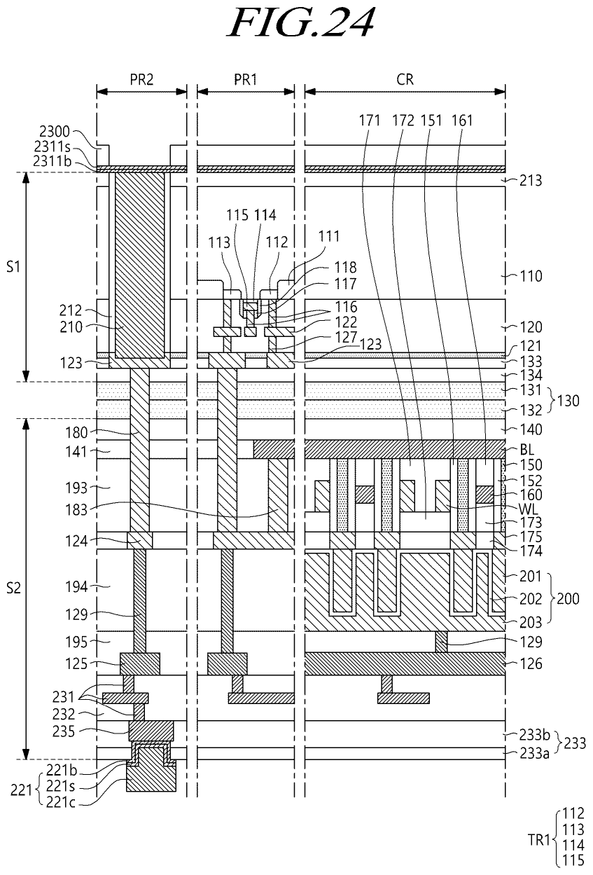

Referring to FIG. 24, a first back barrier material layer 2311b and a first back seed material layer 2311s are sequentially formed on the first back insulating layer 213 and the first through-electrode 210. A photoresist (PR) 2300 is formed on the first back seed material layer 2311s. A portion of the PR 2300 is removed in an area overlapping the first through-electrode 210.

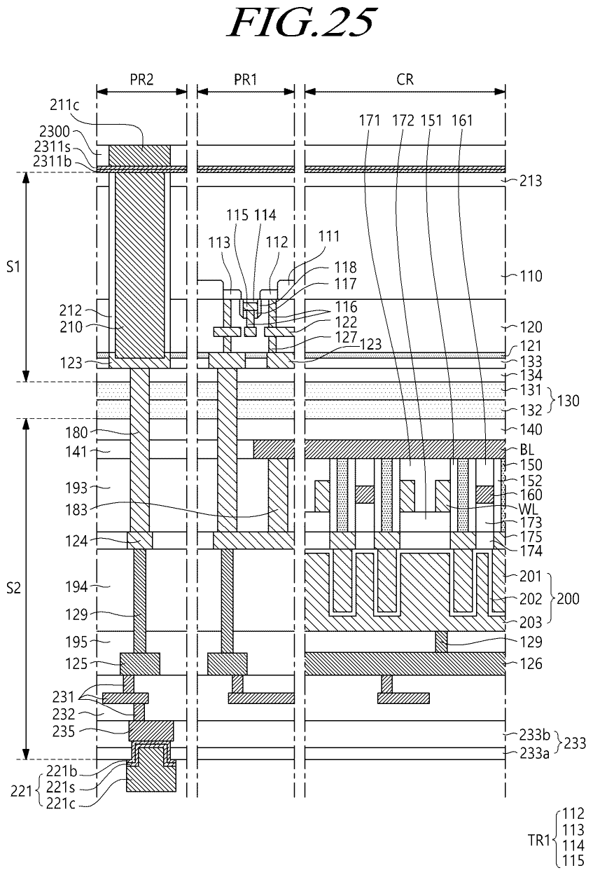

Referring to FIG. 25, a first back conductive layer 211c is formed in an area where the PR 2300 is removed.

Referring to FIG. 3 and FIG. 25, a part of the PR 2300, the first back barrier material layer 2311b and the first back seed material layer 2311s are removed to form a first back pad 211.

Referring again to FIG. 2, the second semiconductor chip C2 may be formed by substantially the same method as the method for manufacturing the memory device described with reference to FIGS. 8 to 25. After the first semiconductor chip C1 and the second semiconductor chip C2 are formed, a solder layer 240 is formed on at least one of the first front pad 221 of the first semiconductor chip C1 and the second back pad 411 of the second semiconductor chip C2. The second semiconductor chip C2 is stacked on the first semiconductor chip C1. The process of stacking the second semiconductor chip C2 on the first semiconductor chip C1 may include a process of connecting the first front pad 221 and the second back pad 411 through the solder layer 240. The process of connecting through the solder layer 240 may include a reflow process. After the first front pad 221 and the second back pad 411 are connected, an encapsulation layer 250 may be formed between the third semiconductor structure S3 and the second semiconductor structure S2.

Referring again to FIG. 7 and FIG. 25, a part of the PR 2300, the first back barrier material layer 2311b and the first back seed material layer 2311s may be removed to form the first back pad 211.

Thereafter, a first front bonding insulating layer 531 is formed to surround the first front pad 221, and a first back bonding insulating layer 533 is formed to surround the first back pad 211. The upper surface of the first front bonding insulating layer 531 may form substantially the same plane as the upper surface of the first front pad 221. The lower surface of the first back bonding insulating layer 533 may form substantially the same plane as the lower surface of the first back pad 211.

Referring again to FIG. 6, the second semiconductor chip C2 may be formed by substantially the same method as the method of manufacturing the memory device described with reference to FIGS. 7 to 25. After the first semiconductor chip C1 and the second semiconductor chip C2 are formed, the second semiconductor chip C2 is stacked on the first semiconductor chip C1. The process of stacking the second semiconductor chip C2 on the first semiconductor chip C1 may include a process of bringing the second back bonding insulating layer 532 into contact with the upper surface of the first front bonding insulating layer 531 and then applying heat. The upper surface of the first front bonding insulating layer 531 is in contact with the lower surface of the second back bonding insulating layer 532. The upper surface of the first front pad 221 is in contact with the lower surface of the second back pad 411.

Referring again to FIG. 3, the memory device includes a first semiconductor structure S1, a second semiconductor structure S2 positioned on the first semiconductor structure S1, a first bonding insulating layer 130 positioned between the first semiconductor structure S1 and the second semiconductor structure S2, and a first connection contact plug 180 which penetrates the first bonding insulating layer 130 to connect the first semiconductor structure S1 and the second semiconductor structure S2 and is connected to the first through-electrode 210.

According to embodiments of the present disclosure, a first through-electrode 210 is disposed within a semiconductor chip including semiconductor structures S1 and S2 bonded to each other using a wafer bonding technique. Since the first through-electrode 210 is connected to the first connection contact plug 180 connecting the bonded semiconductor structures S1 and S2, it is possible to form the electrical connection between the stacked semiconductor chips C1 and C2. Accordingly, it is possible to implement the high integration of the memory device using the wafer bonding technology.

The above description and the accompanying drawings provide an example of the technical idea of the present disclosure for illustrative purposes only. Various modifications, additions and substitutions to the described embodiments will be readily apparent to those skilled in the art without departing from the spirit and scope of the present disclosure. In addition, since the embodiments disclosed in this disclosure are not intended to limit the technical idea of this disclosure but to explain the technical idea of this disclosure, the scope of the technical idea of this disclosure is not limited by these embodiments.

What is claimed is:

1. A memory device comprising:
a first semiconductor structure including a substrate and a through-electrode penetrating the substrate;
a second semiconductor structure positioned over the first semiconductor structure;
a bonding insulating layer disposed between the first semiconductor structure and the second semiconductor structure; and
connection contact plugs penetrating the bonding insulating layer to electrically connect the first semiconductor structure and the second semiconductor structure, at least one of the connection contact plugs being electrically connected to the through-electrode.

2. The memory device of claim 1,
wherein the substrate includes a cell region and a peripheral region, and
wherein the through-electrode is disposed in the peripheral region.

3. The memory device of claim 2,
wherein the peripheral region comprises:
a first peripheral region disposed around the cell region; and
a second peripheral region disposed around the first peripheral region, and
wherein the through-electrode is disposed in the second peripheral region.

4. The memory device of claim 1,
wherein the first semiconductor structure further includes lower wirings each connected to the connection contact plugs, and
wherein at least one of the lower wirings is connected to the through-electrode.

5. The memory device of claim 4, further comprising a capping insulating layer disposed between the lower wirings, the capping insulating layer having a lower surface that forms a same plane as lower surfaces of the lower wirings,
wherein an upper surface of the through-electrode forms a same plane as an upper surface of the capping insulating layer.

6. The memory device of claim 1,
wherein the second semiconductor structure further comprises:
a bit line;
a bit line connection contact having a first side connected to the bit line and extending in a direction perpendicular to an upper surface of the bit line; and
upper wirings, at least one of the upper wirings being connected to a second side of the bit line connection contact, and
wherein at least another one of the upper wirings is connected to the at least one of the connection contact plugs.

7. The memory device of claim 1, further comprising:
a front pad positioned on the second semiconductor structure; and
a back pad positioned beneath the first semiconductor structure,
wherein the through-electrode is connected to the back pad.

8. The memory device of claim 7, further comprising:
a front bonding insulating layer positioned on the second semiconductor structure to surround the front pad; and
a back bonding insulating layer positioned beneath the first semiconductor structure to surround the back pad,
wherein an upper surface of the front bonding insulating layer forms a same plane as an upper surface of the front pad, and a lower surface of the back bonding insulating layer forms a same plane as a lower surface of the back pad.

9. A semiconductor package comprising:
a first semiconductor chip; and
a second semiconductor chip stacked on the first semiconductor chip,
wherein the first semiconductor chip comprises:
a first semiconductor structure including a first substrate and a first through-electrode penetrating the first substrate;
a second semiconductor structure positioned over the first semiconductor structure;
first connection contact plugs disposed to electrically connect the first semiconductor structure and the second semiconductor structure, at least one of the first connection contact plugs being electrically connected to the first through-electrode;
a first front pad positioned on one surface of the second semiconductor structure; and
a first back pad positioned on one surface of the first semiconductor structure and connected to the first through-electrode.

10. The semiconductor package of claim 9, wherein the second semiconductor chip comprises:
a third semiconductor structure including a second substrate and a second through-electrode penetrating the second substrate;
a fourth semiconductor structure positioned over the third semiconductor structure;
second connection contact plugs disposed to electrically connect the third semiconductor structure and the fourth semiconductor structure, at least one of the second connection contact plugs being connected to the second through-electrode;
a second front pad positioned on one surface of the fourth semiconductor structure; and
a second back pad positioned on one surface of the third semiconductor structure and connected to the second through-electrode.

11. The semiconductor package of claim 10, wherein one side of the second back pad is bonded to one side of the first front pad.

12. The semiconductor package of claim 10, further comprising a solder layer disposed between the first front pad and the second back pad.

13. The semiconductor package of claim 9,
wherein the first substrate comprises a cell region and a peripheral region, and
wherein the first through-electrode is disposed in the peripheral region.

14. The semiconductor package of claim 13,
wherein the peripheral region comprises:
a first peripheral region disposed around a cell region; and
a second peripheral region around the first peripheral region, and
wherein the first through-electrode is disposed in the second peripheral region.

15. The semiconductor package of claim 9,
wherein the first semiconductor structure further comprises first lower wirings each connected to the first connection contact plugs, and
wherein at least one of the first lower wirings is connected to the first through-electrode.

16. The semiconductor package of claim 15, further comprising a first capping insulating layer disposed between the first lower wirings, the first capping insulating layer having a lower surface which forms a same plane as lower surfaces of the first lower wirings,
wherein an upper surface of the first through-electrode forms a same plane as an upper surface of the first capping insulating layer.

17. The semiconductor package of claim 9,
wherein the second semiconductor structure further comprises:
a bit line;
a bit line connection contact having a first side connected to the bit line and extending in a direction perpendicular to an upper surface of the bit line; and
first upper wirings, at least one of the first upper wirings being connected to a second side of the bit line connection contact, and
wherein at least another one of the first upper wirings is connected to the at least one of the first connection contact plugs.

18. A method of fabricating a memory device, the method comprising:
forming a capping insulating layer on a first lower insulating layer of a first semiconductor structure;
forming a first through-electrode penetrating the first semiconductor structure;
forming a bonding insulating layer disposed between the first semiconductor structure and a second semiconductor structure;
bonding the second semiconductor structure to the first semiconductor structure; and
forming connection contact plugs penetrating the bonding insulating layer to connect the first semiconductor structure and the second semiconductor structure, at least one of the connection contact plugs being connected to the through-electrode.

19. The method according to claim 18, wherein the forming the first through-electrode penetrating the first semiconductor structure includes performing an etch back process to form the through-electrode.

20. The method according to claim 18, wherein the forming the connection contact plugs connecting the first semiconductor structure and the second semiconductor structure includes forming the connection contact plugs in corresponding peripheral regions of the memory device.
